(19) United States
(12) Patent Application Publication
(10) Pub. No.: US 2022/0238473 A1
(43) Pub. Date: Jul. 28, 2022

(54) METHOD OF MANUFACTURING SEMICONDUCTOR DEVICES AND CORRESPONDING SEMICONDUCTOR DEVICE

(71) Applicant: STMicroelectronics S.r.l., Agrate Brianza (MB) (IT)

(72) Inventors: Dario VITELLO, Merate (LC) (IT); Michele DERAI, Milano (IT)

(73) Assignee: STMicroelectronics S.r.l., Agrate Brianza (MB) (IT)

(21) Appl. No.: 17/573,172

(22) Filed: Jan. 11, 2022

(30) Foreign Application Priority Data
Jan. 25, 2021 (IT) 1020210000001304

(51) Int. Cl. H01L 23/00; H01L 23/495

(52) U.S. Cl. CPC H01L 24/24; H01L 23/49503; H01L 24/19; H01L 2224/24246; H01L 24/96; H01L 24/32; H01L 2224/73267; H01L 2224/32245; H01L 24/97; H01L 24/73

(57) ABSTRACT

A semiconductor chip includes an electrical contact layer covered by a passivation layer. The semiconductor chip is encapsulated in an encapsulation formed by laser-direct-structuring (LDS) material. Laser beam energy is applied to the encapsulation to structure therein a through via passing through the encapsulation and removing the passivation layer at a bonding site of the electrical contact layer of the at least one semiconductor chip. The through via structured in the encapsulation is made electrically conductive so that the electrically-conductive through via is electrically coupled to, optionally in direct contact with, the electrical contact layer at a bonding site where the passivation layer has been removed.

### PRIORITY CLAIM

This application claims the priority benefit of Italian Application for Patent No. 102021000001304, filed on Jan. 25, 2021, the content of which is hereby incorporated by reference in its entirety to the maximum extent allowable by law.

### TECHNICAL FIELD

The description relates to semiconductor devices.

One or more embodiments can be applied to semiconductor devices for the automotive and consumer mass market.

### BACKGROUND

Bonding pad formation (passivation opening, AluCap), testing (which can create scratches on or cracks in the bonding pad structures) and connections (wire bonding or bumping) are experimented to discover various serious issues which may arise, for instance, in wafer fabrication and back-end plant in the production of semiconductor devices such as integrated circuits (ICs).

This has prompted research in the area of contactless testing, which, even after years of use, is still far from providing mature results.

In certain products—for the automotive sector, for instance—product testing (PT) is performed for reliability reasons before passivation deposition. Also, electrical wafer sorting (EWS or probing) is not considered satisfactory, either because pad damage possibly caused by EWS is deemed unacceptable or because radio frequency (RF) testing can only be performed as a final test, which may be unpractical in various circumstances.

There is a need in the art to contribute in addressing the issues discussed in the foregoing.

### SUMMARY

One or more embodiments may relate to a method.

One or more embodiments may relate to a corresponding semiconductor product.

One or more embodiments may involve skipping pad opening with passivation removed over a pad by laser ablation during the formation of through mold vias (TMVs).

In one or more embodiments, die/top metal remain unaffected insofar as they are not exposed (that is, they do not “see” the ambient). This facilitates reducing (and virtually dispensing with) corrosion, pad damage, and similar drawbacks.

Semiconductor devices according to embodiments may exhibit metal (e.g., copper) through-mold-vias (TMVs) contacting the top metal (e.g., copper or aluminum) of the semiconductor chip.

### BRIEF DESCRIPTION OF THE DRAWINGS

One or more embodiments will now be described, by way of example only, with reference to the annexed figures, wherein:

FIGS. 1A, 1B and 1C are illustrative of a conventional approach in providing bonding pads using dedicated photomasks;

FIGS. 2 and 3 are illustrative of embodiments as per the present description with FIG. 3 being a representation on a large scale of the portion of FIG. 2 indicated by arrow III;

FIGS. 4A to 4H are exemplary of possible steps in manufacturing semiconductor devices according to embodiments of the present description; and

FIGS. 5, 6 and 7 are representations on an enlarged scale of results which can be obtained in some of the steps of FIGS. 4A to 4H; specifically, FIGS. 5, 6 and 7 are representations on an enlarged scale of the portions of FIG. 4B, FIG. 4D and FIG. 4E indicated by the arrows V, VI and VII.

It will be appreciated that, for the sake of simplicity and ease of explanation, the various figures may not be drawn to a same scale.

### DETAILED DESCRIPTION

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

It will be appreciated that, unless the context indicates otherwise, like parts or elements are indicated throughout the figures with like reference symbols, and a detailed description will not be repeated for each and every figure for brevity.

Semiconductor devices such as integrated circuits (ICs) may comprise, in a manner known per se to those of skill in the art, a leadframe having arranged thereon one or more semiconductor chips or dice.

The designation leadframe (or lead frame) is currently used (see, for instance the USPC Consolidated Glossary of the United States Patent and Trademark Office) to indicate a metal frame which provides (at a die pad or paddle, for instance) support for a semiconductor chip or die as well as electrical leads to couple the semiconductor chip or die to other electrical components or contacts.

Essentially, a leadframe comprises an array of electrically-conductive formations (leads) which extend from a peripheral location inwardly in the direction of the semiconductor chip or die, thus forming an array of electrically-conductive formations from the die pad having at least one semiconductor chip or die attached thereon.

Electrical coupling of the leads in the leadframe with the semiconductor chip or die may be via wires forming a wire-bonding pattern around the chip or die.

A device package may be completed by an insulating encapsulation formed by molding a compound such as an epoxy resin on the leadframe and the semiconductor chip(s) attached thereon.

Whatever the specific coupling arrangement adopted, a semiconductor chip or die may include bonding pads in order to facilitate electrical connection between a leadframe and a semiconductor chip arranged thereon.

Bonding pads are currently provided as an opening in a passivation layer which facilitates the welding of bonding wires, copper pillars, laser direct structuring (LDS) vias and so on.

Pad opening is one of the last steps of the front end (FE) process flow and is conventionally performed using dedicated photomasks. A device may thus become increasingly expensive as the number of masks used increases.

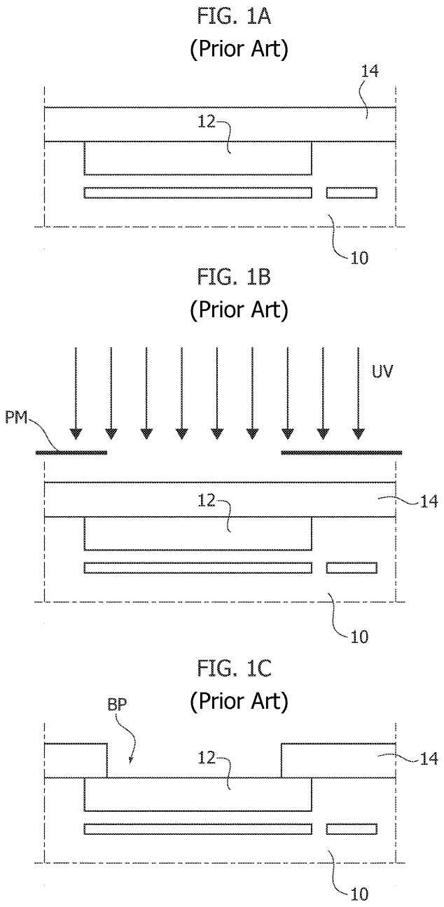

FIGS. 1A, 1B and 1C are illustrative of a conventional approach in providing bonding pads using dedicated photomasks.

FIGS. 1A, 1B and 1C illustrate a (front or top) portion of a semiconductor chip or die 10—not visible in its entirety—having a front or top metal (e.g., copper or aluminum) layer 12 onto which a passivation layer 14 as exemplified in FIG. 1A is formed in a manner known to those of skill in the art.

Various options are available for the material of the layer: copper (Cu) and aluminum (Al) as mentioned above are those most frequently occurring today.

Also, metallization with NiPd or NiPdAu (with passivation 14 further thereon) may be applied to the front or top metal layer 12 in order to increase bonding pad robustness to bonding loads.

FIG. 1B is exemplary of a Photo-resist Mask PM having been exposed to radiation (ultraviolet (UV) radiation, for instance) and developed so as to provide an opening therein being positioned over the passivation layer 14.

An etching process (for example a reactive ion etching (ME)) then removes the passivation layer 14 at those locations not protected by the mask PM thus forming (see FIG. 1C) bonding pads BP at those locations of the top metal layer 12 which are exposed as a result of the localized removal of the passivation layer 14.

An approach as exemplified in FIGS. 1A to 1C suffers from various disadvantages and limitations.

For instance, the positions of the bonding pads in the die are defined once for all at the beginning of device design and cannot be changed easily in view of the intended application of the device (system-in-package (SiP)). Added costs may arise due to use of pad-dedicated masks and the number of the masks used. Also, the top metal exposed in bond pad opening can suffer from contamination and or corrosion from the environment, until the semiconductor chip is assembled in the chip package. This may lead to various chip connection reliability issues.

In one or more embodiments, openings through a passivation layer (to provide bonding pad openings) may be created directly with laser beam energy during the assembly process of the device using laser direct structuring (LDS) technology.

Laser direct structuring is a technology based on laser machining which facilitates structuring lines and vias in a molding compound, with the possibility of growing (plating) metal such as copper onto the structured lines and vias.

Laser direct structuring has already been considered for providing electrical coupling of the leads in a leadframe with a semiconductor chip or die: see, for instance, United States Patent Publication Nos. 2018/342453 A1, 2020/203264 A1 and US 2020/321274 A1, all these documents being assigned to the same assignee of the present application and incorporated herein by reference.

One or more embodiments as illustrated in the following were found to reduce device cost as well as issues associated with front-end (FE) manufacturing, and also to increase device design flexibility (e.g., in SiP applications).

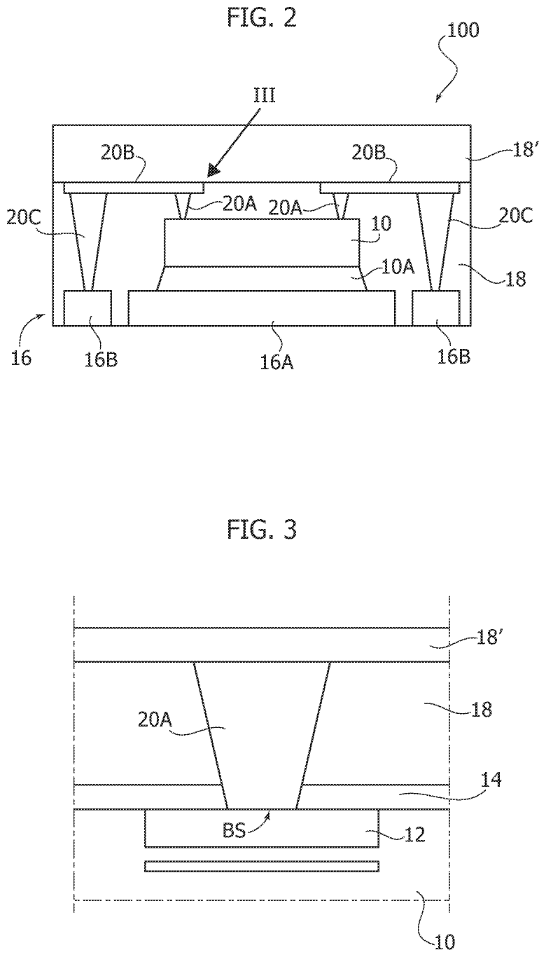

FIG. 2 is a cross-sectional view across a semiconductor device 100 such as an integrated circuit which comprises a leadframe 16 having one or more semiconductor chips or dice 10 arranged thereon (via die-attach material 10A, for instance).

The leadframe 16 has the semiconductor chip or die 10 attached thereon (a single chip or die 10 is illustrated for simplicity) at a die pad 16A and comprises an array of electrically-conductive formations (leads) 16B which extend from a peripheral location inwardly in the direction of the semiconductor chip or die 10, thus forming an array of electrically-conductive formations from the die pad 16A having the semiconductor chip or die 10 attached thereon.

As illustrated in FIG. 2, electrical coupling of the semiconductor chip or die 10 to the leads 16B in the leadframe 16 is provided by electrically conductive formations formed in an insulating encapsulation 18 comprising laser-direct-structuring (LDS) material molded onto the leadframe 16 and the semiconductor chip(s) 10 attached thereon.

As illustrated in FIGS. 2 and 3, such lines and vias may comprise:

first “vertical” through-mold-vias (TMVs) 20A extending through the encapsulation 18 with their distal ends facing (and contacting) the top metal 12 (e.g., copper or aluminum with possible metallization such as NiPd or NiPdAu, for instance) in the chip 10, thus providing mechanical and electrical connection therewith;

“horizontal” lines 20B extending from the proximal ends of the first vias 20A towards the chip 10 essentially parallel to the leadframe 16, the lines 20B having inner ends protruding over the periphery of the chip 10; and

second “vertical” through-mold-vias 20C extending through the encapsulation 18 from the inner ends of the lines 20B and contacting at their distal ends respective leads 16B in the leadframe 16.

Further details on the provision of these vias and lines can be gathered from the commonly-assigned patent documents already cited in the foregoing.

For instance, in arrangements as illustrated in FIGS. 2 and 3 the encapsulation of LDS material 18 may have molded thereon further encapsulation material 18′ of a conventional (non-LDS) type—epoxy resin, for instance—with the lines 20B extending between the two encapsulations 18 and 18′.

One or more embodiments are based on the recognition that the drilling action of the laser beam LB applied to the encapsulation 18 to structure therein the holes for providing (e.g., after metal growth therein, such as plating with copper) the first through-mold-vias 20A may be extended—downwardly, in the representation of FIG. 3—to drill (also) the upper (passivation) layer 14 of the chip or die 10. In that way, the first through-mold-vias (TMVs) 20A may have their distal ends in electrical contact with the top metal 12 (e.g., copper or aluminum) in the chip 10 thus providing mechanical and electrical connection therewith at bonding sites BS which play the role of the conventional bonding pads BP produced as exemplified in FIGS. 1A to 1C.

Such an approach is advantageous in so far as pad contamination is largely avoided: contrary to the conventional pads BP of FIG. 1C, the bonding sites BS as illustrated in FIG. 3 remain closed (unexposed to the outer ambient) while the vias 20A, 20C and the lines 20B are provided.

In that way, “covering” the Cu top metal 12 with other pad finishing to counter Cu corrosion or migration can be avoided.

In one or more embodiments however, the top metal layer 12 may comprise a pad finishing layer like NiPd or NiPdAu.

One or more embodiments may facilitate cost reduction (due, e.g. to reducing and virtually avoiding the use of masks) and a reduction of the front-end (FE) manufacturing flow, with ensuing savings in process time.

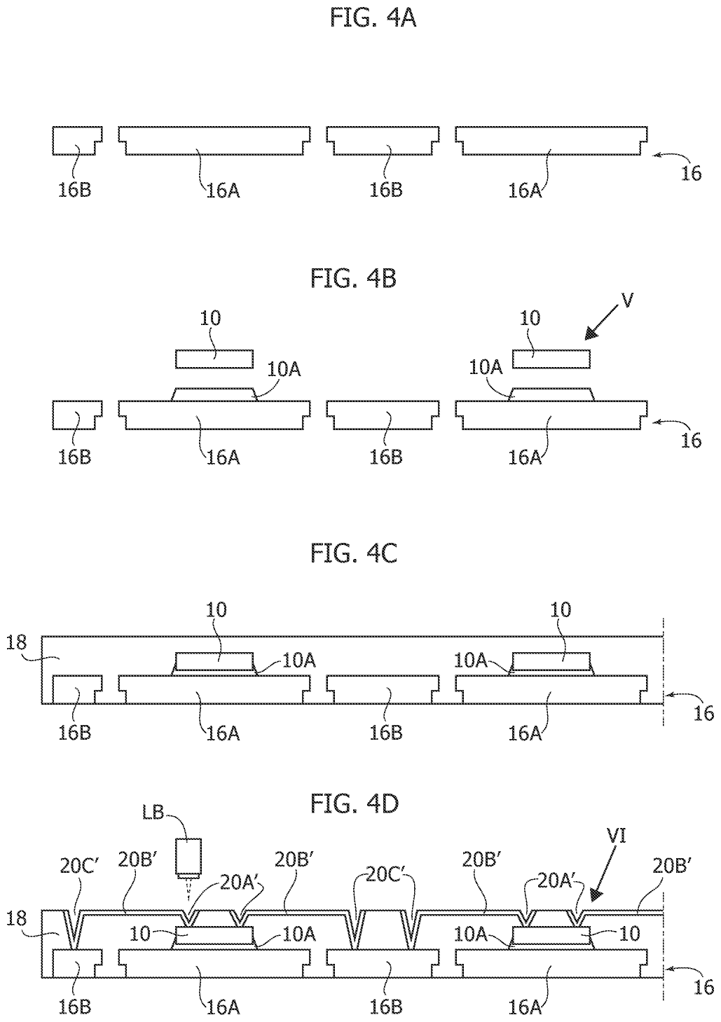

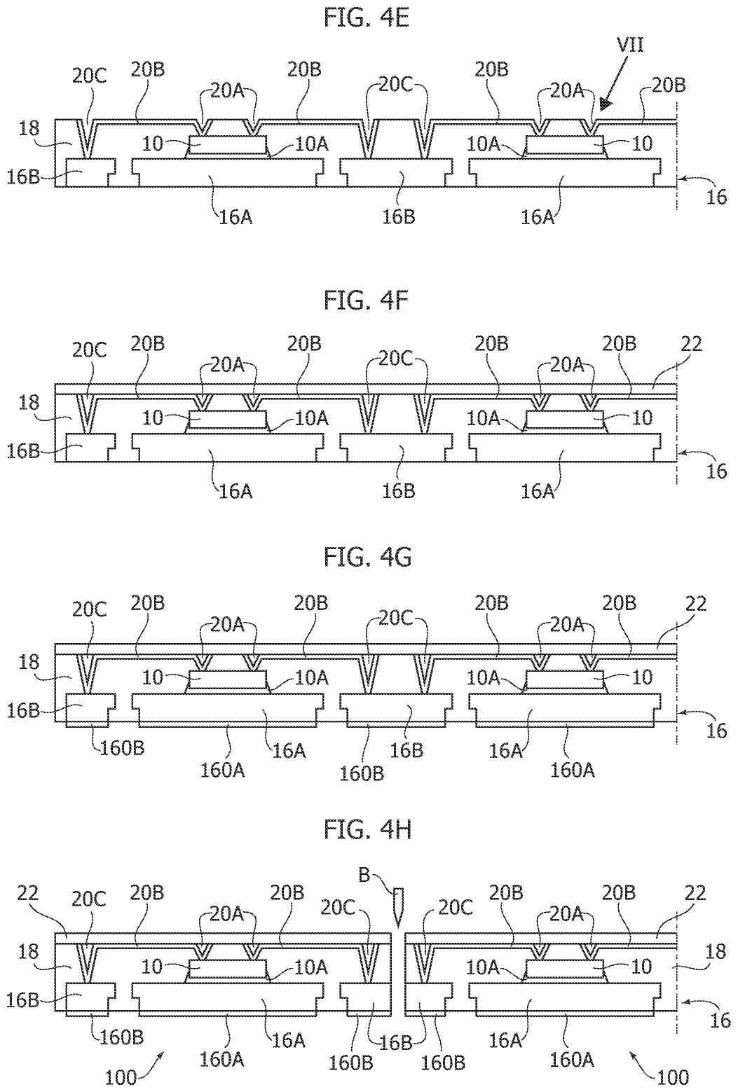

FIGS. 4A to 4H are exemplary of possible steps in manufacturing a semiconductor device 100 of the type exemplified in FIGS. 2 and 3.

FIGS. 4A to 4H refer to manufacturing simultaneously plural devices 100 which are finally separated in a “singulation” step (FIG. 4H) as otherwise conventional in the art.

Those of skill in the art will otherwise appreciate that the sequence of steps of FIG. 4A to 4H is merely exemplary in so far as: one or more steps illustrated can be omitted and/or replaced by other steps; additional steps may be added; and one or more steps can be carried out in a sequence different from the sequence illustrated.

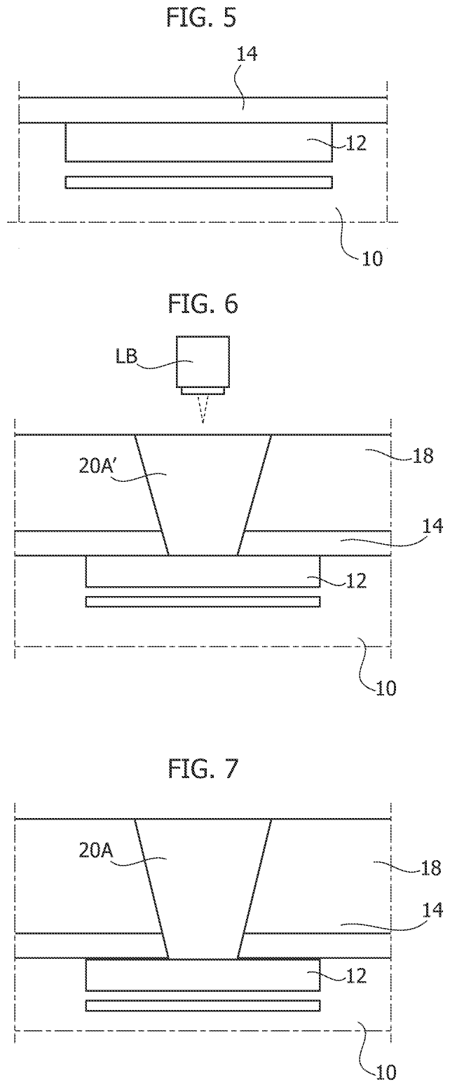

Also, for the sake of simplicity and ease of understanding, unless the context indicates otherwise: parts or elements like parts or elements already discussed in connection with FIGS. 1 to 3 are indicated in FIGS. 4A to 4H (and FIGS. 5, 6 and 7 as well) with like reference symbols, and a detailed description will not be repeated for brevity; and for simplicity, certain details possibly illustrated in FIGS. 1 to 3 may not be reproduced in FIGS. 4A to 4H and 5 to 7.

The steps exemplified in FIGS. 4A to 4H are the following:

FIG. 4A—provision of a (standard) leadframe 16;

FIG. 4B—attachment of chips or dice 10 on die pads 16A of the leadframe: see also FIG. 5 for chip details;

FIG. 4C—molding of encapsulation 18 (including additive included laser-activatable LDS material), via compression molding, for instance;

FIG. 4D—structuring of vias 20A′, 20C′ and lines 20B′ in the encapsulation 18 via laser beam LB (LDS laser machining): results for a via 20A are exemplified in FIG. 6 showing a hole 20A′ laser-drilled through the encapsulation—and—the passivation 14 down to the (top) metal 12 in the chip 10;

FIG. 4E—completion of vias 20A, 20C and lines 20B via metallization (plating with copper, for instance, as conventional in present-day LDS technology). Results for a via 20A filled with electrically-conductive material are exemplified in FIG. 7: the distal end of the via 20A contacts the (top) metal 12 in the chip 10 at a bonding site BS (formed without being exposed to the ambient);

FIG. 4G—plating (e.g., tin plating) at reference 22; and

FIG. 4H—singulation (e.g., via a blade B) to provide individual devices 100.

Briefly, a method as exemplified herein may comprise:

encapsulating (see FIG. 4C, for instance) at least one semiconductor chip (for instance, 10) having an electrical contact layer (for instance, 12) covered by a passivation layer (for instance, 14) in an encapsulation (for instance, 18) comprising laser-direct-structuring, LDS material; and

applying (see FIG. 4D, for instance) laser beam energy (for instance, LB) to the encapsulation (18) structure (see, for instance, 20A′ in FIG. 4D and FIG. 6) therein a through via (see, for instance, 20A in FIG. 7) to the at least one semiconductor chip, wherein laser beam energy applied to the encapsulation to structure therein the through via removes the passivation layer at a bonding site (see, for instance, BS in FIG. 3) of the electrical contact layer of the at least one semiconductor chip.

A method as exemplified herein may comprise making the through via structured in the encapsulation (18) electrically conductive (see, for instance, FIG. 4E), wherein the electrically-conductive through via (for instance, 20A) is electrically coupled (advantageously, in direct contact) to said electrical contact layer at said bonding site with the passivation layer removed (at the bonding site).

A method as exemplified herein may comprise making the electrically-conductive through via (for instance, 20A) contacting said electrical contact layer at said bonding site with the passivation layer removed (at the bonding site).

A method as exemplified herein may comprise:

coupling the at least one semiconductor chip having an electrical contact layer covered by a passivation layer with a die pad (for instance, 16A) in a leadframe (for instance, 16), the leadframe comprising an array of leads (for instance, 16B) around the die pad;

providing said encapsulation comprising LDS material to encapsulate the at least one semiconductor chip coupled to said die pad in the leadframe as well as the array of leads therearound;

applying laser beam energy to the encapsulation (18) structure therein (see, for instance, 20A′, 20B′, 20C′ in FIG. 4D) at least one electrical connection path, the at least one electrical connection path structured in the encapsulation comprising said through via (for instance, 20A′) to the at least one semiconductor chip, a further through via (for instance, 20C′) to the array of leads (16B) of the leadframe as well as an electrical connection (for instance, 20B′) of the further through via to said through via; and

making said through via, said further through via and said electrical connection structured in the encapsulation electrically-conductive, wherein said at least one electrical connection path (for instance, 20A, 20B, 20C) electrically couples said electrical contact layer at said bonding site with at least one lead in the array of leads of the leadframe.

In a Method as Exemplified Herein:

said through via and said further through via may comprise proximal ends opposite the at least one semiconductor chip and the array of leads of the leadframe, respectively; and

said electrical connection of the further through via to said through via may be structured (for instance, 20B′) between said proximal ends of said through via and said further through via.

A method as exemplified herein may comprise applying laser beam energy to a surface of the encapsulation to structure (for instance, 20B′) at said surface said electrical connection of the further through via to said through via.

In a method as exemplified herein, said making electrically conductive may comprise growing electrically conductive material (e.g., plated Cu) subsequent to said applying laser beam energy to the encapsulation.

A device (for instance, 100) as exemplified herein, may comprise:

at least one semiconductor chip (for instance, 10) having an electrical contact layer (for instance, 12) covered by a passivation layer (for instance, 14), the at least one semiconductor chip encapsulated in an encapsulation (for instance, 18) comprising laser-direct-structuring, LDS material; and

an electrically-conductive through via (for instance, 20A) to the at least one semiconductor chip (10), the electrically-conductive through via laser-drilled (see, for instance, LB, 20A′ in FIG. 4D, which can be detected also in the final product) through the LDS material of the encapsulation and through the passivation layer at a bonding site (for instance, BS) of the electrical contact layer of the at least one semiconductor chip, wherein the electrically-conductive through via is electrically coupled to said electrical contact layer at said bonding site.

A device as exemplified herein may comprise:

the at least one semiconductor chip (having an electrical contact layer covered by a passivation layer) being coupled with a die pad (for instance, 16A) in a leadframe (for instance, 16), the leadframe comprising an array of leads (for instance, 16B) around the die pad;

said encapsulation (for instance, 18) comprising LDS material encapsulating the at least one semiconductor chip coupled to said die pad in the leadframe as well as the array of leads therearound; and

at least one electrical connection path (for instance, 20A, 20B, 20C) in the encapsulation, the at least one electrical connection path comprising said electrically-conductive through via (for instance, 20A) to the at least one semiconductor chip, a further electrically-conductive through via (for instance, 20C) to the array of leads of the leadframe as well as an electrical connection (for instance, 20B) of the further through via to said through via, wherein said at least one electrical connection path electrically couples said electrical contact layer at said bonding site (for instance, BS) with at least one lead in the array of leads of the leadframe.

In a device as exemplified herein, said electrically-conductive through via is in contact with said electrical contact layer at said bonding site (for instance, BS).

In a Device as Exemplified Herein:

said through via (for instance, 20A) and said further through via (for instance, 20C) may comprise proximal ends opposite the at least one semiconductor chip and the array of leads of the leadframe, respectively; and said electrical connection (for instance, 20B) is provided between said proximal ends of said through via and said further through via.

In a device as exemplified herein, said electrical connection (for instance, 20B) is provided (see, for instance, FIGS. 4D and 4E) at a surface of the encapsulation comprising LDS material.

A device as exemplified herein may comprise electrically-conductive material grown onto the encapsulation where laser beam energy has been applied.

Without prejudice to the underlying principles, the details and embodiments may vary, even significantly, with respect to what has been described by way of example only without departing from the extent of protection.

The claims are an integral part of the technical teaching on the embodiments as provided herein.

The extent of protection is determined by the annexed claims.

1. A method, comprising:
encapsulating a semiconductor chip having an electrical contact layer covered by a passivation layer in an encapsulation comprising laser-direct-structuring (LDS) material;
applying laser beam energy to the encapsulation to structure therein a through via to the semiconductor chip, wherein the laser beam energy applied to the encapsulation to structure the through via further removes the passivation layer at a bonding site of the electrical contact layer of the semiconductor chip; and
forming an electrically-conductive via in the through via structured in the encapsulation electrically conductive, wherein the electrically-conductive via is electrically coupled to said electrical contact layer at said bonding site where the passivation layer was removed.

2. The method of claim 1, wherein the electrically-conductive via is in direct contact with said electrical contact layer at said bonding site.

3. The method of claim 1, comprising:
coupling the semiconductor chip to a die pad in a leadframe, the leadframe comprising an array of leads around the die pad;
wherein encapsulating further comprises encapsulating the semiconductor chip coupled to said die pad in the leadframe as well as the array of leads with the encapsulation;
applying laser beam energy to the encapsulation to structure therein at least one electrical connection path;
applying laser beam energy to the encapsulation to structure therein a further through via to the array of leads of the leadframe; and
forming an electrical conductor at the at least one electrical connection path and forming a further electrically conductive via at the further through via;
wherein the electrically conductor electrically couples the electrically-conductive via and the further electrically-conductive via so as to electrically couple said electrical contact layer at said bonding site with at least one lead in the array of leads of the leadframe.

4. The method of claim 3, wherein:
said electrically-conductive via and said further electrically-conductive via comprise proximal ends opposite the at least one semiconductor chip and the array of leads of the leadframe, respectively; and
said electrical conductor is structured between said proximal ends of said electrically-conductive via and said further electrically-conductive via.

5. The method of claim 3, wherein applying laser beam energy to the encapsulation to structure therein said at least one electrical connection path comprises applying laser beam energy to a surface of the encapsulation to structure at said surface said at least one electrical connection path between the further through via and said through via.

6. The method of claim 1, wherein forming the electrically-conductive via comprises growing electrically conductive material subsequent to said applying laser beam energy to the encapsulation.

7. A device, comprising:
a semiconductor chip having an electrical contact layer covered by a passivation layer;
an encapsulation comprising laser-direct-structuring (LDS) material that encapsulates the semiconductor chip; and
an electrically-conductive via to the at least one semiconductor chip, the electrically-conductive via comprising: an opening extending through the LDS material of the encapsulation and through the passivation layer at a bonding site of the electrical contact layer of the semiconductor chip, and electrically-conductive material in said opening to make an electrical coupling to said electrical contact layer at said bonding site.

8. The device of claim 7, wherein the electrically-conductive via is in contact with said electrical contact layer at said bonding site.

9. The device of claim 7, comprising:
a leadframe including an array of leads around a die pad;
wherein the semiconductor chip is coupled to the die pad;
wherein said encapsulation further encapsulates the semiconductor chip coupled to said die pad in the leadframe as well as the array of leads therearound; and
at least one electrical connection path in the encapsulation, the at least one electrical connection path comprising said electrically-conductive via to the semiconductor chip, a further electrically-conductive via to the array of leads of the leadframe and an electrical connector between the further electrically-conductive via and said electrically-conductive via, wherein said at least one electrical connection path electrically couples said electrical contact layer at said bonding site with at least one lead in the array of leads of the leadframe.

10. The device of claim 9, wherein:
said electrically-conductive via and said further electrically-conductive via comprise proximal ends opposite the semiconductor chip and the array of leads of the leadframe, respectively; and
said electrical connector is provided between said proximal ends.

11. The device of claim 9, wherein said electrical connector is provided at a surface of the encapsulation.

12. The device of claim 7, comprising electrically conductive material grown onto the encapsulation where laser beam energy has been applied.
